(19) United States
(12) Patent Application Publication
(10) Pub. No.: US 2017/0026238 A1
(43) Pub. Date: Jan. 26, 2017

(54) Time and Motion Tracking of Health Status

(71) Applicant: Cisco Technology, Inc., San Jose, CA (US)

(72) Inventors: Carlos M. Pignataro, Raleigh, NC (US); James D. Stanley, III, Austin, TX (US); Rajesh Vargheese, Austin, TX (US); Gonzalo A. Salgueiro, Raleigh, NC (US)

(21) Appl. No.: 14/808,048

(22) Filed: Jul. 24, 2015

(51) Int. Cl. H04L 12/24; G06F 19/00; G06N 7/00; G01R 21/133

(52) U.S. Cl. CPC H04L 41/0816; G01R 21/133; G06F 19/3431; G06N 7/005

(57) ABSTRACT

A health status for a user is determined at a first network connected device based on health history stored at the first network connected device. Energy usage of a second network connected device utilized by the user is monitored by the first network connected device via messages sent to the first network connected device. A change in the health status of the user is predicted by the first network connected device based upon the messages sent to the first network connected device. Operation of at least one of the second network connected device or another network connected device is modified in response to predicting the change in the health status of the user.

### TECHNICAL FIELD

The present disclosure relates to tracking health status of users, and in particular, leveraging time and motion data sets to track health status.

### BACKGROUND

Health tracking is becoming more important as healthcare costs and human life spans increase. Accordingly, it is particularly important to predict and track individuals' health status as they exercise, and as healthcare is provided to users.

Significant challenges exist in providing healthcare to patients within emergency room environments. For example, emergency room usage is highly unpredictable, and usage is particularly difficult to predict based on historical data. This makes it difficult to efficiently staff emergency rooms. Furthermore, emergency rooms typically have long wait times.

### BRIEF DESCRIPTION OF THE DRAWINGS

FIG. 1 is a flowchart illustrating a process for leveraging time and motion data to track health status, according to an example embodiment.

FIG. 2 is a network environment configured to provide time and motion tracking of health status, according to an example embodiment.

FIG. 3 is a flowchart illustrating a process for using device energy consumption data to track health status, according to an example embodiment.

FIG. 4 is a first flowchart illustrating a process for leveraging time and motion data to predict complications in an emergency room environment, according to an example embodiment.

FIG. 5 is a second flowchart illustrating a process for leveraging time and motion data to predict complications in an emergency room environment, according to an example embodiment.

FIG. 6 is a third flowchart illustrating a process for leveraging time and motion data to predict complications in an emergency room environment, according to an example embodiment.

FIG. 7 is a flow diagram illustrating the calculation of a complication index based upon time and motion data, according to an example embodiment.

FIG. 8 is an illustration of a system for providing a smart exercise health kit that leverages time and motion data, according to an example embodiment.

FIG. 9 is a block diagram of a device configured to perform time and motion tracking of health status, according to an example embodiment.

### DESCRIPTION OF EXAMPLE EMBODIMENTS

### Overview

A health status for a user is determined at a first network connected device based on health history stored at the first network connected device. Energy usage of a second network connected device utilized by the user is monitored by the first network connected device via messages sent to the first network connected device. A change in the health status of the user is predicted by the first network connected device based upon the messages sent to the first network connected device. Operation of at least one of the second network connected device or another network connected device is modified in response to predicting the change in the health status of the user.

### Example Embodiments

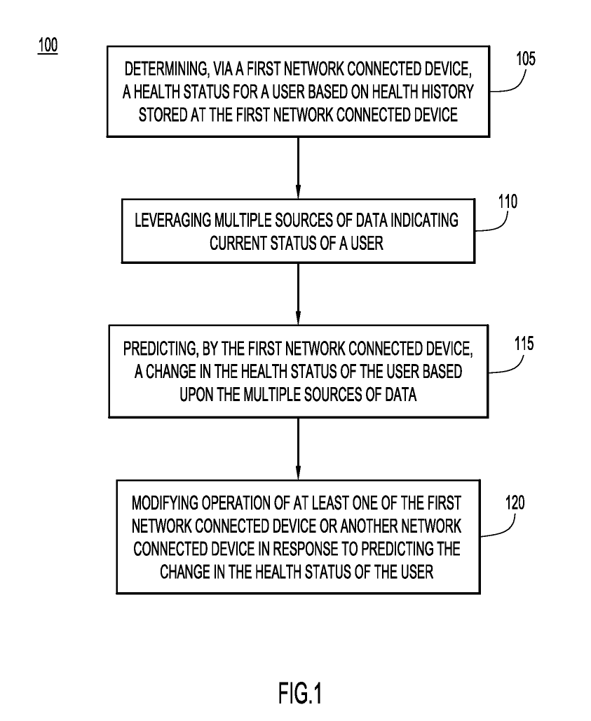

With reference made to FIG. 1, depicted therein is a flowchart 100 illustrating a process that leverages multiple data sources and tracks the time and motion of a user to track changes in a health status of the user. The process of FIG. 1 may use multiple data sources, including energy usage, in order to determine changes in health status, and in particular, predict possible medical complications.

The process of FIG. 1 begins at 105 where a health status for a user is determined. This health status is based on a health history for the user that is stored at a network connected device. In 110, multiple sources of data are leveraged to determine a current status of a user. These multiple sources of data may include:
Energy usage of equipment, including exercise equipment, like treadmills;
Video focused on the user;
Thermal/temperature sensing of the user or the user's environment;
Activity data for the user that may be received from devices such as pedometers, accelerometers, pressure sensors, Global Positioning System sensors, and others;
Electronic Medical Record (EMR) data; and
Pulse and other vital sign data taken for the user.

In other words, the data sources can be grouped into the following categories:
Video cameras, surveillance data sources, and collaboration communications such as video conference systems;
Wireless network (e.g., Wi-Fi®) enabled data sources;
Energy management data sources;
Network management data sources;
Analytics data sources; and
Healthcare vertical solutions data sources

In 115, a prediction is made that there is a likely change in the health status of the user based upon the multiple sources of data. This prediction may be in response to messages received at the network connected device. The messages may be data updates from one or more of the data sources described above. For example, if the energy usage of a treadmill being operated by a user increases or decreases, this change may signal fatigue or overexertion on the part of the user. Accordingly, based on this change in energy usage, a network connected device may predict a change in health status for the user operating the treadmill. According to other examples, messages sent from, for example, devices monitoring a patient in a hospital or emergency room setting can be used to determine a predicted health status change for the user. Determining these health status changes may also be based on determining a health status index, as will be described in greater detail below.

In 120, the operation of a network connected device is modified in response to the predicted change in the health status of the user. Continuing with the treadmill example from above, the modification of the network connected device may include modifying the operation of the treadmill, either raising or lowering the intensity of the workout provided by the treadmill, based upon the predicted change in the health status of the user. According to the hospital example, additional medical equipment and/or sensors may be activated in response to the determination. Still other examples may include hospital or emergency room scheduling equipment that may be modified in response to the predicted change in the user's health status.

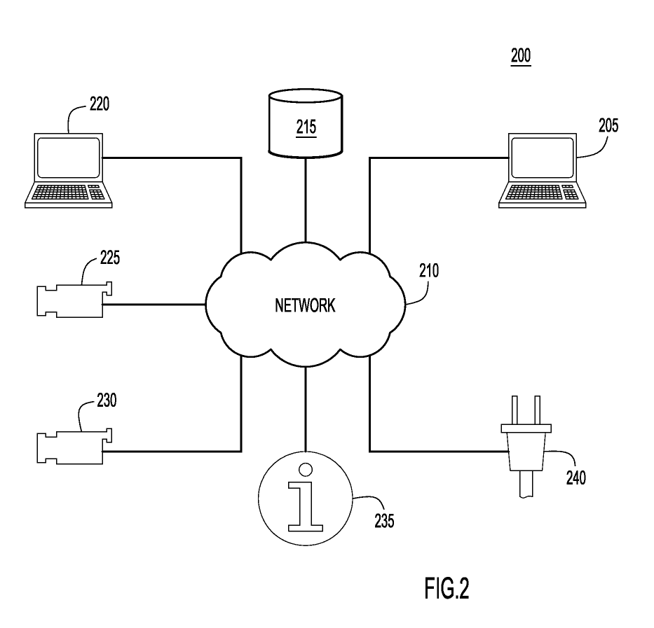

With reference now made to FIG. 2, depicted therein is a network environment 200 configured to carry out a process like that depicted in flowchart 100 of FIG. 1. Specifically, network connected device 205 is connected to network 210, to which database 215, second network connected device 220, video camera 225, thermal camera 230, other sensor/data source 235, and energy usage data source 240 are all also connected. Database 215 may include historical information for a user, such as historical health records or activity tracking data. Network connected device 220 may be any one of numerous computing devices, such as a scheduling computer or a network connected piece of exercise equipment. Additional sensor or information source 235 may be embodied as a medical sensor or other device that may be used to track a patient or user. Energy consumption device 240 may serve as a source of data for the amount of energy used by another sensor device, such as network connected devices 215-235 and/or other devices that are not directly connected to network 210. One or more of devices 215-240 may send network messages through network 210 and the messages are ultimately routed to first network connected device 205. Based on these messages, first network connected device 205 may determine a health status for a user and/or predict a change in the health status of the user, as described above with reference to FIG. 1. Furthermore, first network connected device 205 may send its own messages through network 210 to one or more of devices 215-240 in order to modify the operation of one or more of the devices 215-240 in response to the predicted change in health status.

In other words, the techniques described herein leverage multiple data sources, including energy usage/consumption data, in order to determine a change in, or to predict a change, in a user's health, as will be discussed in greater detail below with reference to FIGS. 2-8. Using an example of user exercising on a piece of network connected exercise equipment, the energy consumption data for the exercise equipment may be combined with video data of the user utilizing the equipment, vital sign data for the user, environmental data for the user's environment, and historical health data for the user to accurately predict a change in the user's health. For example, video data of a user running on a treadmill may indicate that a user's body language is showing signs of fatigue. This data may be combined with the energy consumption data for the treadmill, the vital sign data for the user, and the historical data for the user to predict that the user may be overexerting him or herself. On the other hand, if the energy consumption data indicates that a user may be approaching a state of overexertion, but the video and vital sign data indicate that the user is not overexerting him or herself, the prediction for the user's health may be altered. Accordingly, through the use of multiple data sources, including non-traditional time and motion data sources such as energy consumption data, accurate predictions can be made regarding a user's health status.

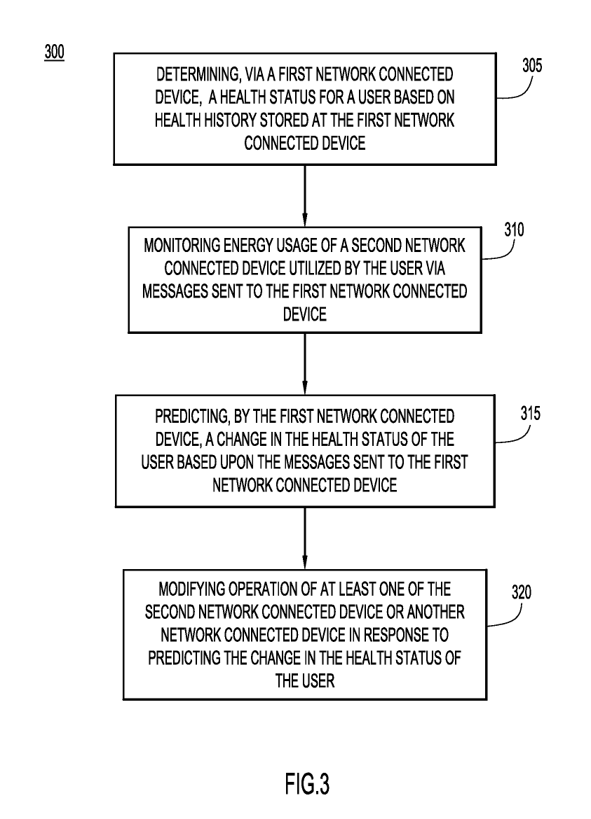

Additionally, the techniques described herein may be used to ensure the safety of a user. Specifically, the modification of one or more of devices 215-240 can be done in response to a predicted change in the user's health. The modification of the one or more of devices 215-240 can be made to ensure the continued safety of the user. For example, the operation of a network connected piece of exercise equipment can be modified to ensure the safety of the user. If the exercise equipment is embodied as a treadmill, the speed or incline of the treadmill may be modified to ensure that the user does not exceed safe exertion limits. If the exercise equipment is embodied as a device that provides resistance training, such as an exercise bike, an elliptical machine, or other variable resistance exercise machines, the resistance of the equipment may be decreased in order to ensure the safety of the user. According to other examples, such as an emergency room environment (as will be described in greater detail with reference to FIG. 3), the safety of the user can be ensured by modifying the operation of network connected devices to ensure that the appropriate devices and medical professionals are present to care for a patient. For example, medical professionals may be automatically paged or contacted, and medical resources such as operating rooms and medical equipment may be automatically reserved for the patient.

With reference now made to FIG. 3, depicted therein is a flowchart 300 in which the techniques described above with reference to FIGS. 1 and 2 are applied to an emergency room (ER) or emergency department environment in order to provide an adaptive ER usage model based upon a complication index. The predictive techniques described herein may be particularly beneficial to ERs for several reasons, including:
ERs may have highly unpredictable usage.
It may be difficult to predict ER utilization based solely on historical data.
ER wait times may be dependent on the specific cases (i.e., patients) present in the ER and not based upon more predictable factors, such as the time of the day.
Due to difficulty in predicting patient complications, appropriate staffing (i.e., staffing with appropriate specialties) may be difficult.
ERs may be costly to service and operate, therefore under utilization and long wait times go hand in hand.

Conventional techniques for predicting ER usage may utilize data that includes:
1) The number of patients currently being provided care by the ER;
2) The number of people waiting in the waiting room;
3) The number of people in the process of being transported to the ER;
4) The number of people that are communicating with care providers over the telephone who may eventually be routed to the ER; and/or
5) The number of people that are experiencing symptoms that could result in an ER event.

The techniques described herein may use the above-listed data sets, but may also include one or more of the following additional data sets:
1) Energy usage. As will be described in more detail below, depending on the complexity of a particular case (i.e., patient), the activation of additional equipment and/or increased usage of equipment may be used to predict complications, and/or interpolate potential time to completion of patient care.
2) Thermal sensing. Identifying people and motion in the presence of a patient may serve as an indication of an increased complexity to a particular case. Accordingly, this information may also be used to predict complications and/or interpolate potential time to completion of patient care.
3) Video data. As with the thermal sensing data, the video data may identify people and motion in the presence of a patient.

For example, if a person is brought into an ER, an operation is in progress, and a complication occurs, additional equipment may be turned on to stabilize the patient, and additional personnel resources may be needed to care for the patient. Furthermore, the time for completing the operation would also be altered. By utilizing the time, motion and presence data sets described above, the complication may be identified, additional personnel may be contacted, and ER wait times for other patients may be updated; one example of which will now be described in further detail with reference to FIG. 3.

The process begins in 305 wherein a health status for a user is determined at a first network connected device. The health status is determined based upon health history that is stored at the first network connected device. This health history may be based on health data gathered by, for example, a smartphone application, a wearable network connected device, such as a step counter or pedometer, a network-connected piece of exercise equipment, such as a treadmill. In other words, the health status may indicate a current fitness level for the user. According to other examples, the stored health data may include electronic medical records, both historical and recently taken.

In 310, energy usage of a second network connected device is monitored. The second network connected device is utilized by the user. For example, the second network connected device may be a network connected piece of exercise equipment, such as a treadmill. According to other examples, the second network connected device may be a piece of medical equipment used to monitor a patient. The monitoring of the second network connected device takes place via messages sent to the first network connected device. These message sent to the first network connected device may take the form of message sent directly from the second network connected device. According to other examples, an intermediary device may send the messages to the first network connected device.

In 315, a prediction is made that there will be a change in the user's health status based on the messages received at the first network connected device. In other words, the prediction is made based on the energy usage of the second network connected device. For example, based upon the energy usage of a network connected treadmill, a prediction may be made about the health status of the user of the treadmill. According to some examples, an increase in energy consumption by the treadmill may indicate a positive change in the health status of the user. Specifically, if the health history for the user indicates a steady improvement in fitness, the increased energy consumption by the treadmill may indicate that the user is continuing to improve his or her fitness. On the other hand, if the energy consumption of the treadmill indicates an exertion level of the user that is outside a safe level (i.e., the treadmill appears to operating at a speed that is faster than the user can handle), the first network connected device may predict that the user is likely to injure of overexert him or herself.

According to other examples, the prediction about the health status of the user may be based upon energy usage of other devices, such as medical devices, medical sensors, or even climate control devices utilized by a user. For example, if newly activated medical sensors are used to monitor a user (accompanied by the increase in energy consumption to facilitate the use of the device), it may be predicted that the user is likely experiencing a health complication.

In 320, a modification is made to at least one of the second network connected device or another network connected device in response to the predicted change in the health status of the user. For example, if the prediction made in 315 indicates that the user of a treadmill is likely to injure or overexert him or herself, the first network connected device may control the treadmill to decrease its speed, incline and/or resistance in order to prevent injury or overexertion to the user. If the energy usage of a medical sensor indicates that a user is likely to experience a medical complication, the first network connected device can take steps to increase monitoring of the patient by the medical sensor, send a message to a network connected device, such as a pager or smart phone, to alert medical professionals of the predicted complication, and/or send messages to a scheduling and/or reservation device to reflect the predicted complication. For example, the first network connected device may reserve additional medical sensors, reserve an operating room, and/or update wait times for other patients based on the predicted complication.

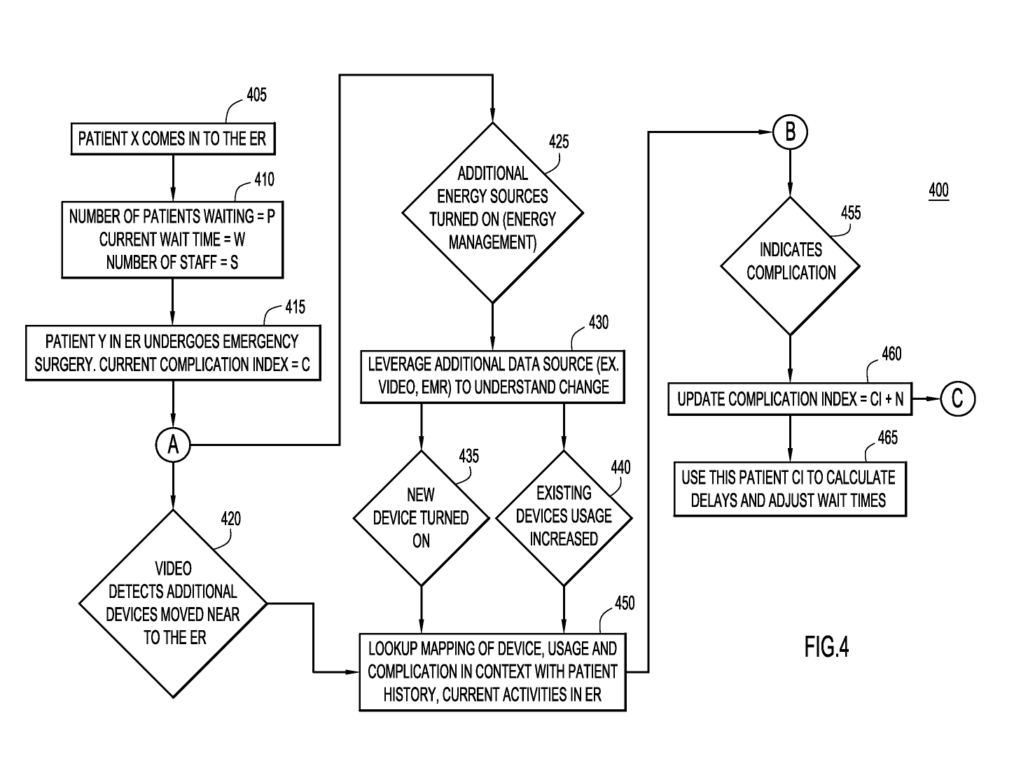

With reference now made to FIG. 4, depicted therein is a flowchart 400 that illustrates a process for calculating the wait time for patients who arrive at the ER based on the energy usage, motion of equipment, and personnel data of ER devices, patients and professionals. This data is used to predict the time to completion, potential outcome for patients, and complications of each patient, which in turn is used to predict wait times for patients. The process begins at 405 where a patient “X” arrives at the ER. At 410, a series of variables are determined, for example, “N” the number of patients waiting (including patient “X”), “W” the current wait time of each patient, and “S” the number of staff currently working in the ER.

In 415, another patient, patient “Y,” undergoes an emergency surgery. A current Complication Index (CI) is calculated for patient “Y.” The complication index “CI” is a function of numerous variables that serves to indicate a level of complexity or severity of a patient's condition. In other words, a CI is a calculation that combines multiple data sources, including non-traditional time and motion data sources, to accurately predict the current and/or future status of a user's health. Because the CI includes multiple data sources, it may provide an accurate indication for a patient's current status. For example, a complication index may be defined as follows:

CI=f(Device_proximity, Order_of_device_activation, Staff_Movement);

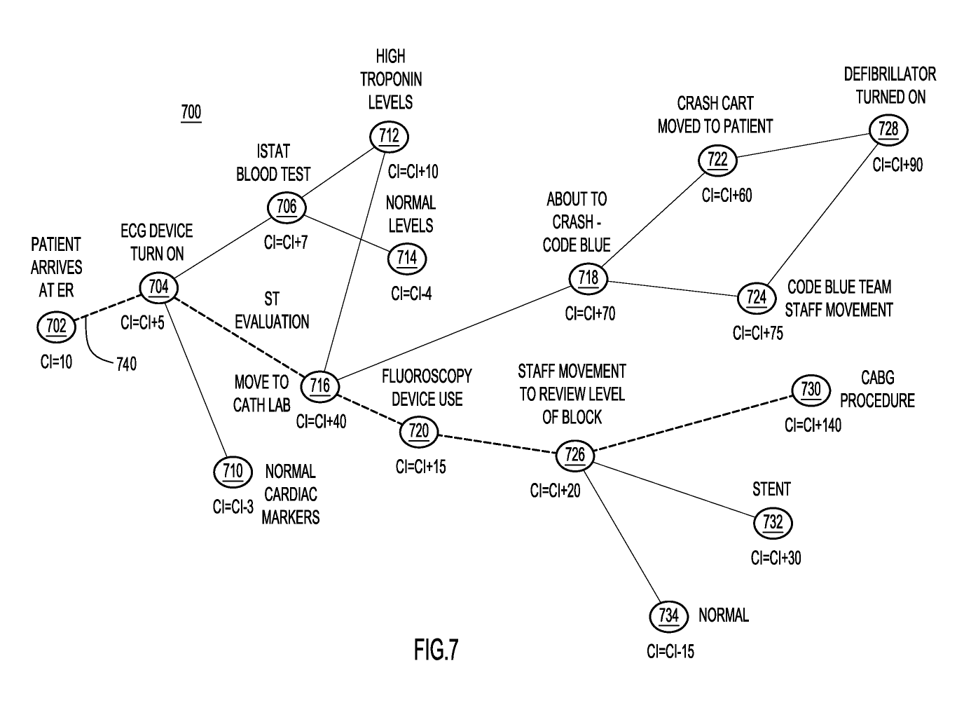

An example of how a CI is calculated and updated will be described in greater detail below with reference to FIG. 7.

At node “A” in FIG. 4 a network connected device, such as device 205 of FIG. 2, will begin tracking the CI for a patient based on information received from network connected devices, such as network connected devices 215-240 of FIG. 2. For example, following the branch of flowchart 400 that goes from node “A” to 425, the network connected device determines that additional energy sources have been turned on. These additional devices may be medical sensors, or other medical devices. In 430 additional data sources may be leveraged to determine what this increased energy usage means for the patient. For example, depending on the type of device that is activated in 425, the additional data sources leveraged in 430 may indicate that the patient is likely undergoing some type of complication. As will be described in more detail with reference to FIG. 7 below, specific devices may be correlated with specific complications. Also included in these additional data sources may be video data or ER staffing information. For example, if video data identifies a particular staff member as entering the patient's room, and ER staffing information indicates that the staff member has a cardiology specialty, it may be determined that the patient is experiencing a heart-related complication. Furthermore, as illustrated through 435 and 440, additional devices and increased power consumption by existing devices may further be used to predict complications for a patient.

In conjunction with the data acquired through 425-440, video data received at 420 may also detect additional devices that have been moved near the patient, even if the devices have not yet been activated. In addition to video data, other types of data, such as data acquired from radio tags applied to devices may also be utilized to determine that devices have been moved near the patient.

In 450, the data acquired in 420-440 is combined (e.g., a mapping of the different devices may be generated), and a look-up is performed by the network connected device for possible complications that would require the different devices. Supplementing the device data may be the historical information about the patient, such as the patient's electronic medical records. In 455, it is determined whether or not the data indicates a complication. If a complication is indicated, the CI for the patient is updated. In 465, the updated CI is used to calculate delays and wait times for other patients. In other words, the current weight time “W” for patient “X” may be updated based on the complication. Furthermore, dynamic staffing changes may take place in response to the complication. Accordingly, additional staff members may be paged or automatically telephoned or emailed in order to accommodate the increased wait times and/or to treat the determined indication.

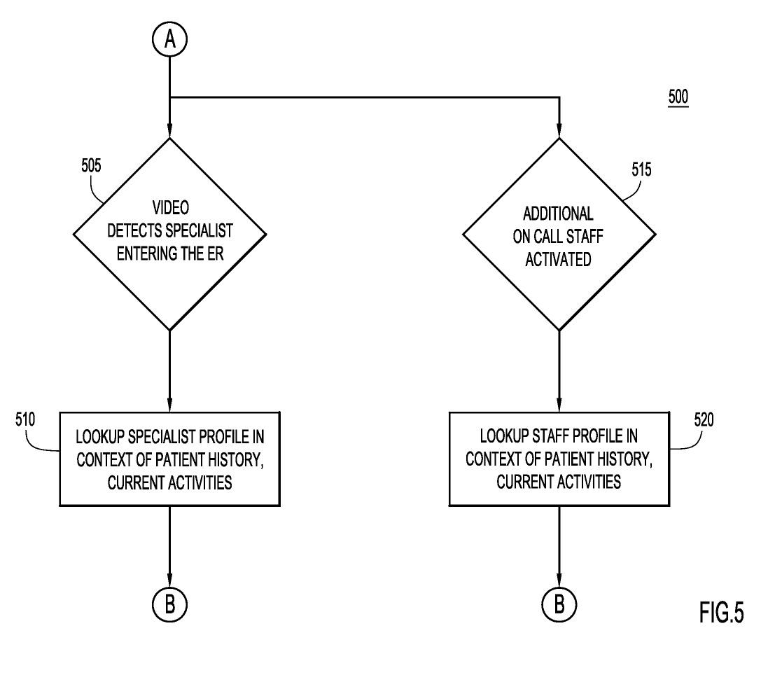

With reference now made to FIG. 5, depicted therein are alternative operations of flowchart 400 shown in FIG. 4. Specifically, operations 505-520 of FIG. 5 may supplement or replace operations 420-450 arranged between nodes “A” and “B” of FIG. 4. By leveraging operations 505-520 of FIG. 5 in conjunction with operations 420-450 FIG. 4, the combination of the two figures illustrates how multiple data sources may be used to accurately predict the health status of a user.

Unlike the device data of operations 420-450 of FIG. 4, operations 505-520 of FIG. 5 utilize personnel and staffing data to predict a complication. For example, in 505, video data detects a specialist entering the ER and/or a patient's examination room. In 510, the network connected device will search for and locate the specialist's personnel profile. Based on the specialty of the specialist, a complication may be predicted for a patient. A patient's history may be combined with the staff profile in order to accurately predict the complication. Similarly, in 515, the network connected device receives an indication that additional staff has been activated. The network connected device will look-up the staff profiles of the additional staff in 520. Based upon the content of the staff profiles, a complication for the patient may be predicted. The searching of the staff profiles in 520 may also be done in conjunction or within the context of the medical history of the patient to accurately predict complications for the patient.

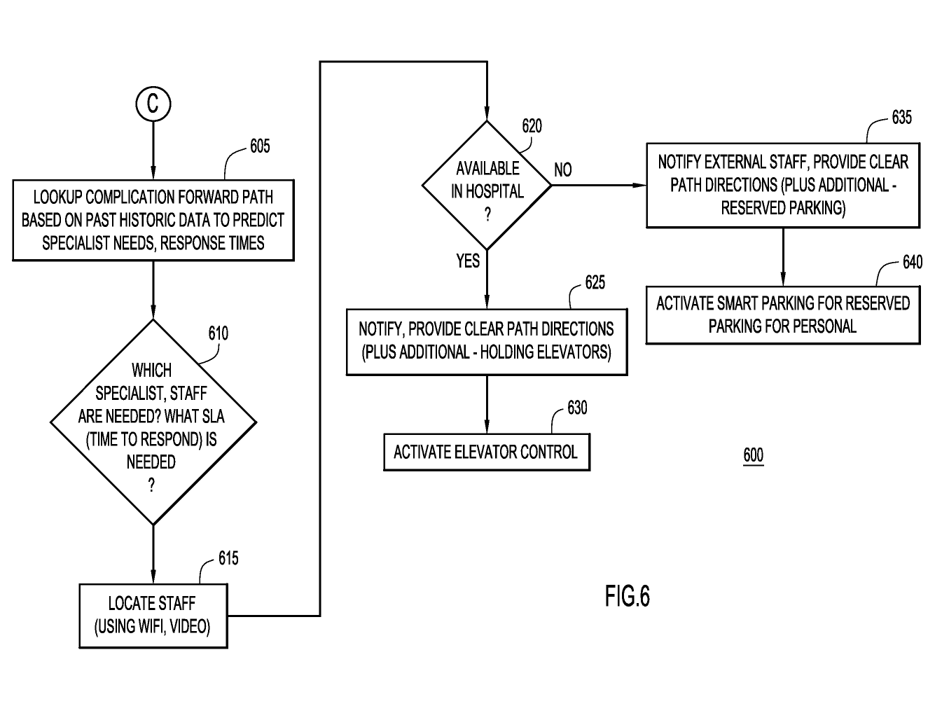

With reference now made to FIG. 6, depicted therein is a flowchart 600 which illustrates additional steps that can be included in conjunction with those of FIGS. 4 and 5. Specifically, the operations of flowchart 600 may be performed in conjunction with those of FIG. 4 starting at node “C.” In 605, the complication predicted in 460 of FIG. 4 will be used to perform a look-up that may predict staffing and/or specialists that will be needed to treat the complication. Included in this look-up may be a determination as to the response time within which the specialist and/or staff care should be provided to the patient. In 610, the staffing, specialist, and response time needs are determined. In 615, a lookup is performed to determine where the necessary staff and/or specialists are currently located. The location may be performed using video data, radio tag data, internet data such as an Internet Protocol address or access point currently being used by the staff member, and/or historical records. In 620, the location of the staff and/or specialists is evaluated to determine if they are located within the ER and/or hospital grounds. If the staff and/or specialist is located on the grounds, they are notified in 625, and in 630 steps are taken to facilitate relocating the staff/specialist to the patient's location. For example, elevators may be sent to the location where the staff/specialist is located. According to other examples, transport personnel may be dispatched to the staff/specialist's location in order to bring the staff/specialist to the patient's location. On the other hand, if the staff/specialist is not on the ER/hospital premises, the staff/specialist is alerted in 635. The alert may also include instructions to facilitate the staff/specialist's speedy relocation to the ER/hospital location. These instructions may include providing the staff/specialist with updated driving and/or parking instructions. In 640, steps are taken to facilitate relocating the staff/specialist to the patient's location, including reserving a parking space for the staff/specialist.

With reference now made to FIG. 7, depicted therein is an example flow diagram 700 for a complication index “CI.” The specific changes made to the index are tuned based on past data and available technologies and expertise. The flow diagram 700 calculates the complication index to determine a wait time for patients in an ER. As illustrated in flow 700, as a patient's status changes, the CI flows to a different one of nodes 702-734. Each of nodes 702-734 represents a change in the patient's CI, and includes a corresponding change in value to the patient's CI. One particular flow through flow diagram 700 is illustrated by the dashed line 740.

The flow begin at node 702 when the patient arrives at the ER. A patient's initial arrival is accompanied by a default CI, which in the example of FIG. 7 is a value of 10. Accordingly, at node 702:

CI=10

As the CI increases for the patient, this increase in CI will be reflected as an increase in wait times for other patients in the ER.

Subsequent to the patient's arrival, an electrocardiogram (ECG) device is turned on and used to take measurements of the patient. The energy usage of the ECG device will be sent to a network connected device through network messages. Accordingly, the CI for the patient will be updated by the network connected device. Specifically, the activation of the ECG device causes the CI to be increased by a value of 5 for a CI of 15, as illustrated at node 704:

CI=CI+5=15

Based on this new CI value, the wait times for other patients may be increased. If the ECG device indicates normal cardiac markers for the patient, the flow would move to node 710, where the CI would be decreased, as would the predicted wait times for other patients. In flow 740, on the other hand, the ECG device indicates an ST elevation, which may indicate a complication, such as a myocardial infarction. Therefore, the patient is moved to the catheterization laboratory (Cath Lab). This movement of the patient to the Cath Lab may be reflected in the patient's medical records, or it may be captured via video or thermal sensors. The record and/or sensor information may be sent to the network connected device, which will increase the CI for the patient based on the patient's presence in the Cath Lab, as illustrated by node 716.

CI=CI+40=55

Once in the Cath Lab, a fluoroscopy device is activated. The energy consumption of the fluoroscopy device is relayed to the network connected device, which increases the CI for the patient, as illustrated by node 720.

CI=CI+15=70

Upon completion of the fluoroscopy, video and/or thermal sensors may indicate that a staff member, such as a radiologist, has moved into the Cath Lad to read the results of the scan. Accordingly, this data is transmitted to the network connected device, the CI for the patient is increased, and flow 700 moves to node 726.

CI=CI+20=90

As with the other increases in the CI, the increase in the CI at nodes 716, 720 and 726 will also be reflected in the wait times for the other patients in the ER. The final step in flow 740 is to node 730 where a coronary artery bypass surgery (CABG) procedure is carried out on the patient. Specifically, the network connected device may determine that the CABG procedure is taking place based on the patient's electronic medical records, the movement of the patient to an operating room, the presence of a staff member who specializes in CABG procedures, or a combination thereof, all of which may be conveyed to the network connected device via network messages. In response to the CABG procedure, the CI for the patient is increased, as illustrated in node 730, and the wait times for other patients are updated to the reflect the change in the CI.

CI=CI+140=230

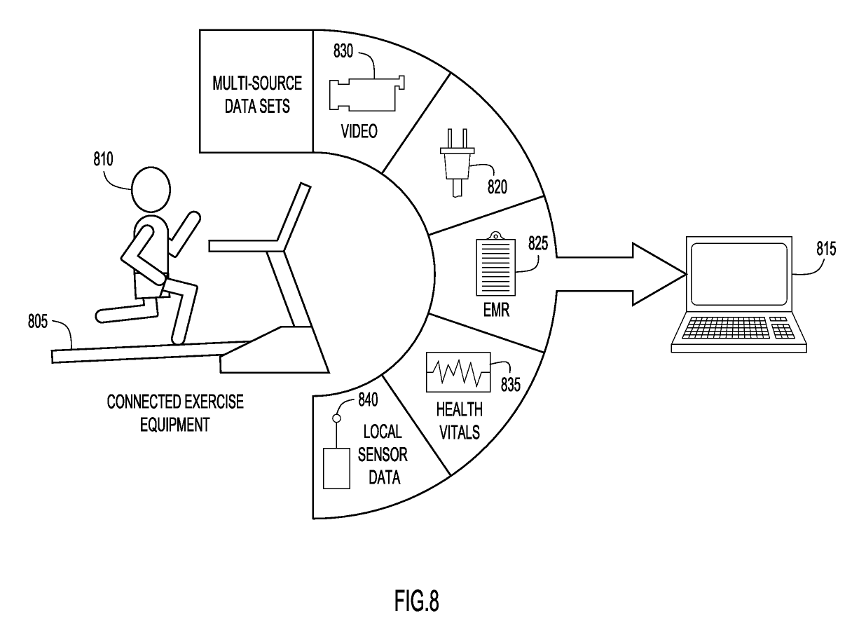

With reference now made to FIG. 8, depicted therein is an additional embodiment of the processes of FIGS. 1 and 3. Unlike the examples of FIGS. 4-7, FIG. 8 is not directed to an ER facility. Instead, the example of FIG. 8 provides a smart exercise health kit that leverages multiple data sources and tracks the time and motion of the user to identify and warn the user of potential injuries and/or overexertion.

Specifically, network connected exercise equipment 805, which in one example is a treadmill in FIG. 8, is being used by a user 810. Treadmill 805 may send data, such as energy consumption data 820, to network connected device 815. Energy consumption data 820 may also include data about the status of treadmill 805, such as the current speed of the treadmill and/or the current incline at which treadmill 805 is operating. Network connected device 815 may be a network connected device like device 205 of FIG. 2. Device 815 may also be one or more network connected devices that provide “cloud” computing services. Also sent to network connected device 815 is historical data 825. Historical data 825 may include electronic medical record data and/or activity tracking data. Based on the historical data, network connected device 815 may determine a health status for user 810, as described with reference to 305 of FIG. 3. Furthermore, network connected device 815 may monitor energy data 820, as described in 310 of FIG. 3, and predict a change in the user's health status, as described above with reference to 315 of FIG. 3. Finally, network connected device 815 may alter the operation of treadmill 805 in response to the predicted change in the health status of the user, as described with reference to 320 of FIG. 3. Specifically, network connected device 815 may alter the operation of treadmill 805 to ensure the safety of user 810.

In addition to energy consumption data 820 and historical data 825, video data 830, user vital sign data 835, and local sensor data 840 may also be provided to network connected device 815. Video data 830 may be video of the user 810 operating treadmill 805, which may be evaluated for signs of fatigue, distress, or ease of operation. For example, video data 830 may include facial recognition data, expression monitoring data, and other data that may be used with pattern recognition/detection to determine key visual signs of fatigue. The vital sign data 835 may include pulse rate, heart rate, blood pressure, body temperature, blood oxygen saturation, breathing, and other information that can be used to evaluate the current status of user 810. Local sensor data 840 may provide data about the environment in which user 810 is operating treadmill 805, including the temperature and humidity of the location of user 810. The local sensor data may also include pedometer data, activity tracker data, accelerometer data (indicating how forceful the user's steps are), and other data co-located with user 810 and/or treadmill 805. Some or all of these multiple data sources may be leveraged to provide an accurate prediction for the user's currently and/or future health status.

There are several possible user notification scenarios that can be implemented based on the different data yielded by the various data sources 820-840. In one scenario, user 810 increases the speed on treadmill 805. Network connected device 815 utilizes a pre-programmed algorithm (that takes into account health risk factors and injury-prone scenarios determined from historical data 825) to alert user 810 to slow down by using the derived insight from the aforementioned multiple data sources.

The notification flow may include the following. Network connected device 815 proactively alerts user 810 that user 810 is approaching a dangerous condition based the historical data 825 of user 810 and real-time analysis of exercise or activity based upon energy consumption data 820, video data 840, vital sign data 835 and/or local sensor data 840. Network connected device 815 modifies the operation of treadmill 805 and/or prevents treadmill 805 from operating beyond the safe limits for user 810. Network connected device 815 may incrementally adjust the operation of treadmill 805 in order to safely increase the effectiveness of the workout provided by treadmill 805, based upon energy consumption data 820, video data 840, vital sign data 835 and/or local sensor data 840.

Furthermore, network connected device 815 may calculate a Exercise Real-Time Health Risk Index (ERTHRI) that can notify user 810 when user 810 is exercising outside the safe bounds for user 810. Accordingly, network connected device 815 may also proactively mitigate high risk exertion scenarios by auto-adjusting the exercise equipment based on the weighting factors of the ERTHRI.

The ERTHRI index is an algorithm that is a function of the variety of simultaneous data sources (e.g., the historical data 825 of user 810 and real-time analysis of exercise or activity based upon energy consumption data 820, video data 840, vital sign data 835 and/or local sensor data 840) that can provide derived medical/health insight on user 810 and set a safe operating boundary for treadmill 805. According to one example, the ERTHRI is defined as follows:

ERTHRI=f(historical health data, current and sustained rate of exercise operation derived from energy use from the equipment, local sensor, video data, vital sign monitoring).

Accordingly, the ERTHRI leverages multiple, non-traditional time and motion data sources to accurately determine current health risks for the user. Based on this real-time index, an algorithm can be implemented to determine the best fit for an exercise profile that is within the determined inner boundary limit based on real-time multi-source data correlations of the past and current performance of user 810 during an exercise program. By maintaining user data over multiple previous exercise programs, the accuracy of the algorithm may be improved. Accordingly, network connected device 815 may make predictive calculations based on current and historical data for the ERTHRI. This allows network connected device 815 to suggest an optimized exercise profile for user 810, and if desired, proactively auto-adjust the operation of treadmill 805 based on the ERTHRI and derived optimal exercise program of user 810.

Furthermore, network connected device 815 may utilize a closed feedback loop whereby the historical data 825 is continuously updated based on cumulative exercise programs along with any additional reporting based on risk indicators encountered during an exercise program.

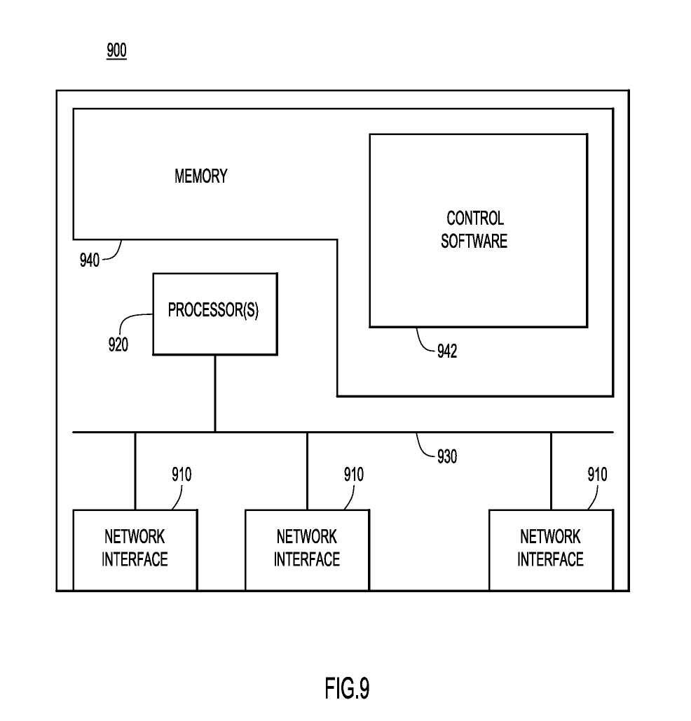

With reference now made to FIG. 9, an example block diagram is shown of a device 900 that may be any one of the network connected devices described above with reference to FIGS. 1-8. Accordingly, device 900 is configured to perform the techniques described herein. Device 900 includes network interfaces (e.g., network ports) 910 which may be used to receive and send packets over a network. The network interfaces 910 may included as part of a network interface unit (e.g., a network interface card). Accordingly, network interfaces 910 may be embodied as a wired interface, a wireless interfaces, an optical interface, an electrical interface, or a combination thereof. One or more processors 920 are provided to coordinate and control device 900. The processor 920 is, for example, one or more microprocessors or microcontrollers, and it communicates with the network interfaces 910 via bus 930. Memory 940 stores software instructions 942 which may be executed by the processor 920. For example, control software 942 for device 900 includes instructions for performing the health based monitoring and prediction described above with reference to FIGS. 1-8. In other words, memory 940 includes instructions for device 900 to carry out the operations described above in connection with FIGS. 1-8. Memory 940 may also store the data sent from data sources described above by reference numerals 215-235 of FIG. 2 and/or reference numerals 820-840 of FIG. 8. This data may be stored in a database in memory 940, and control software 942 may allow the processor 920 to access the data.

Memory 940 may include read only memory (ROM), random access memory (RAM), magnetic disk storage media devices, optical storage media devices, flash memory devices, electrical, optical or other physical/tangible (e.g. non-transitory) memory storage devices. Thus, in general, the memory 940 may be or include one or more tangible (non-transitory) computer readable storage media (e.g., a memory device) encoded with software comprising computer executable instructions. When the instructions of the control software 942 are executed (by the processor 920), the processor is operable to perform the operations described herein in connection with FIGS. 1-8.

In summary, provided herein are methods that determined the health status for a user. This health status may be based on a health history for the user that is stored at a network connected device. Multiple sources of data may be leveraged to determine a current status of a user. A prediction is made that there is a likely change in the health status of the user based upon the multiple sources of data. The operation of a network connected device is modified in response to the predicted change in the health status of the user. Methods are also described in which a health status for a user is determined at a first network connected device based on health history stored at the first network connected device. Energy usage of a second network connected device utilized by the user is monitored by the first network connected device via messages sent to the first network connected device. A change in the health status of the user is predicted by the first network connected device based upon the messages sent to the first network connected device. Operation of at least one of the second network connected device or another network connected device is modified in response to predicting the change in the health status of the user.

As provided herein are devices including a processor, a network interface, and a memory. The processor is configured to determine a health status for a user based on health history stored in the memory. The processor monitors energy usage of a network connected device utilized by the user via messages received over the network interface, and predicts a change in the health status of the user based upon the messages. The operation of at least one of the network connected device or another network connected device is modified by the processor in response to predicting the change in the health status of the user.

Finally, tangible, non-transitory, computer readable storage media are provided in which the instructions encoded thereon cause a processor to determine a health status for a user based on health history stored in a memory. The instructions further cause the processor to monitor energy usage of a network connected device utilized by the user via messages received over a network, and predict a change in the health status of the user based upon the messages. The instructions cause the operation of at least one of the network connected device or another network connected device to be modified by the processor in response to predicting the change in the health status of the user.

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. A method comprising:
determining, via a first network connected device, a health status for a user based on health history stored at the first network connected device;
monitoring energy usage of a second network connected device utilized by the user via messages sent to the first network connected device;
predicting, by the first network connected device, a change in the health status of the user based upon the messages sent to the first network connected device; and
modifying operation of at least one of the second network connected device or another network connected device in response to predicting the change in the health status of the user.

2. The method of claim 1, wherein:
determining the health status for the user comprises determining a fitness level for the user; and
monitoring energy usage of the second network connected device comprises receiving messages indicating energy usage of a piece of exercise equipment.

3. The method of claim 1, wherein:
determining the health status for the user comprises determining a first medical complication for the user; and
monitoring energy usage of the second network connected device comprises receiving messages indicating energy usage of a piece of medical equipment currently monitoring the user.

4. The method of claim 1, further comprising receiving messages from a network connected sensor currently monitoring the user.

5. The method of claim 4, wherein predicting the change in the health status of the user comprises combining sensor data from the messages received from the network connected sensor with energy usage data received from the second network connected device to predict the change in the health status.

6. The method of claim 1, wherein monitoring energy usage of the second network connected device comprises measuring a change in energy usage of the second network device, and further comprising:
receiving messages from a third network connected device; and
utilizing the messages from the third network connected device to correlate the change in energy usage of the second network connected device with the predicted change in the health status.

7. The method of claim 1, wherein predicting the change in health status comprises generating a health index for the user.

8. The method of claim 7, wherein the health index provides a predicted medical complication for the user.

9. The method of claim 1, wherein modifying operation of the at least one of the second network connected device or another network connected device comprises modifying the operation of the second network connected device to accommodate the predicted change in the health status of the user.

10. The method of claim 1 wherein modifying operation of the at least one of the second network connected device or another network connected device comprises controlling a communication network connected device to notify a medical professional of the predicted changed in the health status of the user.

11. An apparatus comprising:
a memory;
a network interface; and
a processor, wherein the processor is configured to:
determine a health status for a user based on health history stored in the memory;
monitor energy usage of a network connected device utilized by the user via messages received over the network interface;
predict a change in the health status of the user based upon the messages; and
modify operation of at least one of the network connected device or another network connected device in response to predicting the change in the health status of the user.

12. The apparatus of claim 11, wherein the processor is further configured to:
determine the health status for the user by determining a fitness level for the user; and
monitor energy usage of the network connected device by receiving messages indicating energy usage of a piece of exercise equipment.

13. The apparatus of claim 11, wherein the processor is further configured to:
determine the health status for the user by determining a first medical complication for the user; and
monitor energy usage of the network connected device by receiving messages indicating energy usage of a piece of medical equipment currently monitoring the user.

14. The apparatus of claim 11, wherein the processor is further configured to receive messages from a network connected sensor currently monitoring the user.

15. The apparatus of claim 14, wherein the processor is configured to predict the change in the health status of the user by combining sensor data from the messages received from the network connected sensor with energy usage data received from the network connected device to predict the change in the health status.

16. A non-transitory computer readable storage media, encoded with instructions, wherein the instructions, when executed by a processor, cause the processor to:
determine a health status for a user based on health history stored in a memory;
monitor energy usage of a network connected device utilized by the user via messages received over a network;
predict a change in the health status of the user based upon the messages; and
modify operation of at least one of the network connected device or another network connected device in response to predicting the change in the health status of the user.

17. The computer readable storage media of claim 16, wherein the instructions further cause the processor to:
determine the health status for the user by determining a fitness level for the user; and
monitor energy usage of the network connected device by receiving messages indicating energy usage of a piece of exercise equipment.

18. The computer readable storage media of claim 16, wherein the instructions further cause the processor to:
determine the health status for the user by determining a first medical complication for the user; and
monitor energy usage of the network connected device by receiving messages indicating energy usage of a piece of medical equipment currently monitoring the user.

19. The computer readable storage media of claim 16, wherein the instructions further cause the processor to receive messages from a network connected sensor currently monitoring the user.

20. The computer readable storage media of claim 19, wherein the instructions further cause the processor to predict the change in the health status of the user by combining sensor data from the messages received from the network connected sensor with energy usage data received from the network connected device to predict the change in the health status.
